(19) United States
(12) Patent Application Publication
(10) Pub. No.: US 2013/0075897 A1
(43) Pub. Date: Mar. 28, 2013

(54) SEMICONDUCTOR INTEGRATED CIRCUIT DEVICE FOR DRIVING DISPLAY DEVICE AND MANUFACTURING METHOD THEREOF

(71) Applicant: Renesas Electronics Corporation, Kawasaki-shi (JP)

(72) Inventors: Atsushi OBUCHI, Nanae (JP); Kazuhisa HIGUCHI, Nanae (JP); Kazuo OKADO, Tokyo (JP); Kazuto MITSUI, Tokyo (JP); Shusaku MIYATA, Tokyo (JP)

(73) Assignee: RENESAS ELECTRONICS CORPORATION, Kawasaki-shi (JP)

(21) Appl. No.: 13/680,777

(22) Filed: Nov. 19, 2012

Related U.S. Application Data
(62) Division of application No. 12/575,665, filed on Oct. 8, 2009.

(30) Foreign Application Priority Data
Nov. 12, 2008 (JP) 2008-289570

(51) Int. Cl. H01L 23/48

(52) U.S. Cl. CPC H01L 23/48
USPC 257/737

(57) ABSTRACT

A semiconductor integrated circuit device for driving an LCD, COG chip packaging is performed. To achieve this, an elongate and relatively thick gold bump electrode is formed over an aluminum-based pad having a relatively small area. In a wafer probe test performed after formation of the gold bump electrode, a cantilever type probe needle having gold as a main component and having an almost perpendicularly bent tip portion is used. The diameter of this probe needle in the vicinity of its tip is usually almost the same as the width of the gold bump electrode. This makes it difficult to perform the wafer probe test stably. To counteract this, a plurality of bump electrode rows for outputting a display device drive signal are formed such that the width of inner bump electrodes is made greater than the width of outer bump electrodes.

### CROSS-REFERENCE TO RELATED APPLICATIONS

This application is a continuation of U.S. patent application Ser. No. 12/575,665, filed Oct. 8, 2009, which claims priority to Japanese Patent Application No. 2008-289570 filed Nov. 12, 2008, the disclosure of which, including the specification, drawings and abstract is incorporated herein by reference in its entirety.

### BACKGROUND OF THE INVENTION

The present invention relates to the structure of a bonding pad group in a semiconductor integrated circuit device and a technology effective when applied to a wafer testing technology in a manufacturing method of a semiconductor integrated circuit device (or a semiconductor device).

Japanese Unexamined Patent Publication No. 2002-196353 (Patent Document 1) or U.S. Pat. No. 6,678,028 (Patent Document 2) corresponding thereto discloses a technology of, in an LSI (Large Scale Integration) device chip for LCD (Liquid Crystal Display) driver, laying out two rows of bonding pad groups in such a manner that bonding pads of the bonding pad group belonging to the row close to the edge portion of the chip have an elongate shape with a small area, while bonding pads of the bonding pad group belonging to the row distant from the edge portion of the chip have a relatively wide shape with a large area.

Japanese Unexamined Patent Publication No. 2006-179931 (Patent Document 3) or US Patent Laid-Open No. 2006-0131726 (Patent Document 4) corresponding thereto discloses a technology of, in typical LSI device chips, laying out two rows of bonding pad groups in such a manner that bonding pads of the bonding pad group belonging to the row close to the edge portion of the chip have an elongate shape, while bonding pads of the bonding pad group belonging to the row distant from the edge portion of the chip have the substantially same area as the former ones but are arranged differently from the former ones.

Japanese Unexamined Patent Publication No. Hei7 (1995)-273119 (Patent Document 5) discloses a technology of, in typical LSI device chips for TCP (Tape Carrier Package) mounting, laying out two rows of bonding pad groups in such a manner that bonding pads of the bonding pad group belonging to the row close to the edge portion of the chip have a shape with a small area, while bonding pads of the bonding pad group belonging to the row distant from the edge portion of the chip have a shape with a large area.

Japanese Unexamined Patent Publication No. Hei7 (1995)-235564 (Patent Document 6) or U.S. Pat. No. 5,569,964 (Patent Document 7) corresponding thereto also discloses a technology of, in typical LSI device chips for TCP mounting, laying out two rows of bonding pad groups in such a manner that bonding pads of the bonding pad group belonging to the row close to the edge portion of the chip have a shape with a small area, while bonding pads of the bonding pad group belonging to the row distant from the edge portion of the chip have a shape with a large area.

Japanese Unexamined Patent Publication No. 2005-189834 (Patent Document 8) or US Patent Laid-Open No. 2005-0122297 (Patent Document 9) corresponding thereto discloses a technology of, in LSI device chips for LCD driver, dividing one row of bonding pads into a plurality of groups of bonding pads and bringing a probe in contact with one of the bonding pads in the group, whereby all of the bonding pads in the group are simultaneously tested.

### [Patent Document 1]

Japanese Unexamined Patent Publication No. 2002-196353

### [Patent Document 2]

U.S. Pat. No. 6,678,028

### [Patent Document 3]

Japanese Unexamined Patent Publication No. 2006-179931

### [Patent Document 4]

US Patent Laid-Open No. 2006-0131726

### [Patent Document 5]

Japanese Unexamined Patent Publication No. Hei7 (1995)-273119

### [Patent Document 6]

Japanese Unexamined Patent Publication No. Hei7 (1995)-235564

### [Patent Document 7]

U.S. Pat. No. 5,569,964

### [Patent Document 8]

Japanese Unexamined Patent Publication No. 2005-189834

### [Patent Document 9]

US Patent Laid-Open No. 2005-0122297

### SUMMARY OF THE INVENTION

In semiconductor integrated circuit devices (for example, LCD driver IC) having a driver for driving a display device such as LCD (Liquid Crystal Display), COG (Chip On Glass) packaging is employed for chip packaging. In order to achieve this, an elongate and relatively thick gold bump electrode, for example, having a width of about 10 μm, length of about 150 μm, and thickness of about 15 μm is formed over an aluminum-based bonding pad having a relatively small area. In a wafer probe test to be performed after the formation of this gold bump electrode, a cantilever type probe needle having gold as a main component and having a tip bent almost perpendicularly to the main body is usually used. The diameter in the vicinity of the tip of the probe needle is typically about 15 μm. In consideration of narrowing tendency of the pitch between gold bump electrodes, it will be more difficult to carry out a wafer probe test in future.

The present invention has been made in order to overcome the above-described problem.

An object of the present invention is to provide a technology of laying out bump electrodes suited for use in semiconductor integrated circuit devices for driving display devices.

The above-described and the other objects and novel features of the invention will be apparent by the description and accompanying drawings herein.

The outline of the typical inventions disclosed herein will next be described briefly.

The present invention relates to a semiconductor integrated circuit device (semiconductor chip) for driving a display device which carries out a wafer probe test by bringing a probe needle into contact with one or some electrodes in a bump electrode group, wherein bump electrodes for outputting display device drive signals are arranged in a plurality of rows and the width of each of the bump electrodes arranged on the inner portion of the chip is made greater than the width of the bump electrodes arranged on the outer portion of the chip.

Advantages available by the typical invention, of the inventions disclosed herein, will next be described briefly.

In the present invention, in a semiconductor integrated circuit device (semiconductor chip) for driving a display device which carries out a wafer probe test by bringing a probe needle into contact with one or some electrodes in a bump electrode group, bump electrodes for outputting display device drive signals are arranged in a plurality of rows and the width of each of the bump electrodes arranged on the inner portion of the chip is made greater than the width of the bump electrodes arranged on the outer portion of the chip so that the wafer probe test can be carried out by not bringing a probe needle into contact with the narrow bump electrodes on the outer portion of the chip but bringing the probe needle into contact with one or all of the wider bump electrodes on the inner portion of the chip.

### BRIEF DESCRIPTION OF THE DRAWINGS

FIG. 1 is a schematic cross-sectional view illustrating a device structure prior to bump formation in a manufacturing method of a semiconductor integrated circuit device according to an embodiment of the invention;

FIG. 2 is a schematic cross-sectional view illustrating a device structure in a UBM (Under Bump Metal) formation step in the manufacturing method of the semiconductor integrated circuit device according to the embodiment of the invention;

FIG. 3 is a schematic cross-sectional view showing a device structure after completion of a photoresist application step in the manufacturing method of the semiconductor integrated circuit device according to the embodiment of the invention;

FIG. 4 is a schematic cross-sectional view illustrating a device structure after completion of a photoresist development step in the manufacturing method of the semiconductor integrated circuit device according to the embodiment of the invention;

FIG. 5 is a schematic cross-sectional view illustrating a device structure after completion of a plating step in the manufacturing method of the semiconductor integrated circuit device according to the embodiment of the invention;

FIG. 6 is a schematic cross-sectional view illustrating a device structure after completion of a resist removal step in the manufacturing method of the semiconductor integrated circuit device according to the embodiment of the invention;

FIG. 7 is a schematic cross-sectional view illustrating a device structure after completion of a UBM etching step in the manufacturing method of the semiconductor integrated circuit device according to the embodiment of the invention;

FIG. 8 is a circuit diagram showing a coupling relationship between the semiconductor integrated circuit device (liquid crystal driver) according to the embodiment of the invention and a liquid crystal panel (liquid crystal display device);

FIG. 9 is a plan layout diagram of a joined portion showing an actual coupling relationship between the semiconductor integrated circuit device (liquid crystal driver) according to the embodiment of the invention and a liquid crystal panel (liquid crystal display device);

FIG. 10 is a cross-sectional view (corresponding to the X3-X4 cross-section of FIG. 9) showing the state before coupling of the semiconductor integrated circuit device (liquid crystal driver) according to the embodiment of the invention and the liquid crystal panel (liquid crystal display device);

FIG. 11 is a cross-sectional view (corresponding to the X3-X4 cross-section of FIG. 9) showing the state after coupling of the semiconductor integrated circuit device (liquid crystal driver) according to the embodiment of the invention and the liquid crystal panel (liquid crystal display device);

FIG. 12 is a plan layout diagram (corresponding to FIG. 9) showing a mutual relationship between drive output bump electrode rows and drive output ITO leads after coupling of the semiconductor integrated circuit device (liquid crystal driver) according to the embodiment of the invention and the liquid crystal panel (liquid crystal display device);

FIG. 13 is a plan layout diagram showing the relationship between drive output bump electrode rows of the semiconductor integrated circuit device (liquid crystal driver) according to the embodiment of the invention and probe needles in wafer probe testing;

FIG. 14 is a schematic cross-sectional view of a probe showing the rough configuration of a prober to be used in a wafer probe testing step in the manufacturing method of the semiconductor integrated circuit device (liquid crystal driver) according to the embodiment of the invention;

FIG. 15 is a cross-sectional view (corresponding to the Y2-Y3 cross-section of FIG. 13) illustrating the shape of a probe needle of a probe card to be used in the wafer probe testing step in the manufacturing method of the semiconductor integrated circuit device (liquid crystal driver) according to the embodiment of the invention;

FIG. 16 is a cross-sectional view (corresponding to the X5-X6 cross-section of FIG. 13) showing the relationship between the tip portions of the probe needles and the second inner output bump electrode row in the wafer probe testing step in the manufacturing method of the semiconductor integrated circuit device (liquid crystal driver) according to the embodiment of the invention;

FIG. 17 is a circuit diagram (when a drive output of the second inner drive output bump electrode itself is measured) showing the behavior of a test circuit placed in a chip region in the wafer probe testing step in the manufacturing method of the semiconductor integrated circuit device (liquid crystal driver) according to the embodiment of the invention;

FIG. 18 is a circuit diagram (when a drive output of the outer drive output bump electrode is measured) showing the behavior of the test circuit placed in the chip region in the wafer probe testing step in the manufacturing method of the semiconductor integrated circuit device (liquid crystal driver) according to the embodiment of the invention;

FIG. 19 is a circuit diagram (when a drive output of the first inner drive output bump electrode is measured) showing the behavior of the test circuit placed in the chip region in the wafer probe testing step in the manufacturing method of the semiconductor integrated circuit device (liquid crystal driver) according to the embodiment of the invention;

FIG. 20 is an in-chip circuit layout diagram of the semiconductor integrated circuit device (liquid crystal driver) according to the embodiment (similar to the other embodiments) of the invention;

FIG. 21 is an on-chip bump electrode layout diagram of the semiconductor integrated circuit device (liquid crystal driver) according to another embodiment (similar to the other embodiments) of the invention;

FIG. 22 is an enlarged on-chip bump electrode layout diagram (corresponding to the enlarged chip end-portion E of FIG. 21) of the semiconductor integrated circuit device (liquid crystal driver) according to the other embodiment (similar to the other embodiments) of the invention;

FIG. 23 is a detailed layout diagram of the on-chip drive output bump electrode of the semiconductor integrated circuit device (liquid crystal driver) according to the other embodiment (similar to the other embodiments) of the invention;

FIG. 24 is a detailed layout diagram of the on-chip non-drive output bump electrode of the semiconductor integrated circuit device (liquid crystal driver) according to the other embodiment (similar to the other embodiments) of the invention;

FIG. 25 is a perspective plan layout diagram (layers are removed gradually to facilitate viewing of the peripheral part) illustrating the relationship between the drive output bump electrodes and the aluminum-based interconnects illustrated in FIG. 23;

FIG. 26 is a device cross-sectional view corresponding to the X2-X1 cross-section of the outer drive output bump electrode portion illustrated in FIG. 25 (essentially the same in the inner drive output bump electrode portion); and

FIG. 27 is a device cross-sectional view corresponding to the X2-Y1 cross-section of the outer drive output bump electrode portion illustrated in FIG. 25 (essentially the same in the inner drive output bump electrode portion).

### DETAILED DESCRIPTION OF THE PREFERRED EMBODIMENTS

### Outline of Embodiments

First, typical embodiments of the invention disclosed herein will be outlined.

1. A semiconductor integrated circuit device for driving a display device, comprising the following: (a) a rectangular semiconductor chip having first and second short sides and first and second long sides at least 5 times longer than the short sides; (b) an outer output bump electrode row for outputting a display device drive signal which electrode row is placed along and in the vicinity of the first long side over the device surface of the rectangular semiconductor chip; and (c) an inner output bump electrode row for outputting a display device drive signal which electrode row is placed along, more inward than, and in the vicinity of the outer output bump electrode row for outputting a display device drive signal over the device surface of the rectangular semiconductor chip; wherein (1) outer output bump electrodes belonging to the outer output bump electrode row and inner output bump electrodes belonging to the inner output bump electrode row each have a major portion containing a gold-based metal having gold as a main component; wherein (2) the width of each of the inner output bump electrodes along the first long side is made wider than the width of each of the outer output bump electrodes along the first long side; and wherein (3) the rectangular semiconductor chip has, over the device surface thereof, a test circuit for conducting an electrical test by not bringing a probe needle into contact with each of the outer output bump electrodes but bringing the probe needle into contact with the other bump electrodes not belonging to the outer output bump electrode row.

2. The semiconductor integrated circuit device for driving a display device as described above in item 1, wherein each of the outer output bump electrodes belonging to the outer output bump electrode row has substantially the same area as each of the inner output bump electrodes belonging to the inner output bump electrode row.

3. The semiconductor integrated circuit device for driving a display device as described above in item 1 or 2, wherein each of the outer output bump electrodes belonging to the outer output bump electrode row and each of the inner output bump electrodes belonging to the inner output bump electrode row are formed over respectively corresponding aluminum-based metal bonding pads having aluminum as a main component; and wherein the area of the outer output bump electrodes and the area of the inner output bump electrodes are greater than the area of the respectively corresponding bonding pads.

4. The semiconductor integrated circuit device for driving a display device as described above in any one of items 1 to 3, wherein the pitch of the outer output bump electrodes belonging to the outer output bump electrode row and the pitch of the inner output bump electrodes belonging to the inner output bump electrode row are substantially the same and at the same time, constant.

5. The semiconductor integrated circuit device for driving a display device as described above in any one of items 1 to 4, wherein a center position, in a pitch direction, of each of the inner output bump electrodes belonging to the inner output bump electrode row is substantially shifted from a center position, in a pitch direction, of an interconnect corresponding thereto on the side of the display device.

6. The semiconductor integrated circuit device for driving a display device as described above in any one of items 1 to 5, further comprising: (d) a bump electrode row for I/O or power supply terminals arranged along and in the vicinity of the second long side over the device surface of the rectangular semiconductor chip; wherein an area of each of bump electrodes for I/O or power supply terminals belonging to the bump electrode row for I/O or power supply terminals is greater than the area of each of the inner output bump electrodes belonging to the inner output bump electrode row.

7. The semiconductor integrated circuit device for driving a display device as described above in any one of items 1 to 6, wherein the display device is a liquid crystal display device.

8. A semiconductor integrated circuit device for driving a display device, comprising the following: (a) a rectangular semiconductor chip having first and second short sides and first and second long sides at least 5 times longer than the short sides; (b) an outer output bump electrode row for outputting a display device drive signal which electrode row is placed along and in the vicinity of the first long side over the device surface of the rectangular semiconductor chip; and (c) an inner output bump electrode row for outputting a display device drive signal which electrode row is placed along, more inward than, and in the vicinity of the outer output bump electrode row for outputting a display device drive signal over the device surface of the rectangular semiconductor chip; wherein (1) outer output bump electrodes belonging to the outer output bump electrode row and inner output bump electrodes belonging to the inner output bump electrode row have the substantially same area and have a major portion containing a gold-based metal having gold as a main component; and wherein (2) the width of each of the inner output bump electrodes along the first long side is made wider than the width of each of the outer output bump electrodes along the first long side.

9. The semiconductor integrated circuit device for driving a display device as described above in item 8, wherein each of the outer output bump electrodes belonging to the outer output bump electrode row and each of the inner output bump electrodes belonging to the inner output bump electrode row are formed over respectively corresponding aluminum-based metal bonding pads having aluminum as a main component; and wherein the area of the outer output bump electrodes and the area of the inner output bump electrodes are greater than the area of the respectively corresponding bonding pads.

10. The semiconductor integrated circuit device for driving a display device as described above in item 8 or 9, wherein the pitch of the outer output bump electrodes belonging to the outer output bump electrode row and the pitch of the inner output bump electrodes belonging to the inner output bump electrode row are substantially the same and at the same time, constant.

11. The semiconductor integrated circuit device for driving a display device as described above in any one of items 8 to 10, wherein a center position, in a pitch direction, of each of the inner output bump electrodes belonging to the inner output bump electrode row is substantially shifted from a center position, in a pitch direction, of an interconnect corresponding thereto on the side of the display device.

12. The semiconductor integrated circuit device for driving a display device as described above in any one of items 8 to 11, further comprising: (d) a bump electrode row for I/O or power supply terminals arranged along and in the vicinity of the second long side over the device surface of the rectangular semiconductor chip; wherein an area of each of bump electrodes for I/O or power supply terminals belonging to the bump electrode row for I/O or power supply terminals is greater than the area of each of the inner output bump electrodes belonging to the inner output bump electrode row.

13. The semiconductor integrated circuit device for driving a display device as described above in any one of items 8 to 12, wherein the display device is a liquid crystal display device.

14. A semiconductor integrated circuit device for driving a display device, comprising the following: (a) a rectangular semiconductor chip having first and second short sides and first and second long sides at least 5 times longer than the short sides; (b) an outer output bump electrode row for outputting a display device drive signal which electrode row is placed along and in the vicinity of the first long side over the device surface of the rectangular semiconductor chip; (c) a first inner output bump electrode row for outputting a display device drive signal which electrode row is placed along, more inward than, and in the vicinity of the outer output bump electrode row for outputting a display device drive signal over the device surface of the rectangular semiconductor chip, and (d) a second inner output bump electrode row for outputting a display device drive signal which electrode row is placed along, more inward than, and in the vicinity of the first inner output bump electrode row for outputting a display device drive signal over the device surface of the rectangular semiconductor chip; wherein (1) outer output bump electrodes belonging to the outer output bump electrode row, first inner output bump electrodes belonging to the first inner output bump electrode row, and second inner output bump electrodes belonging to the second inner output bump electrode row have the substantially same area and have a major portion containing a gold-based metal having gold as a main component; and wherein (2) the width of each of the first inner output bump electrodes and each of the second inner output bump electrodes along the first long side is made wider than the width of each of the outer output bump electrodes along the first long side.

15. The semiconductor integrated circuit device for driving a display device as described above in item 14, wherein each of the outer output bump electrodes belonging to the outer output bump electrode row and each of the first inner output bump electrodes belonging to the first inner output bump electrode row are formed over respectively corresponding aluminum-based metal bonding pads having aluminum as a main component; and wherein the area of the outer output bump electrodes, the area of the first inner output bump electrodes, and the area of the second inner output bump electrodes are greater than the area of the respectively corresponding bonding pads.

16. The semiconductor integrated circuit device for driving a display device as described above in item 14 or 15, wherein the pitch of the outer output bump electrodes belonging to the outer output bump electrode row, the pitch of the first inner output bump electrodes belonging to the first inner output bump electrode row and the pitch of the second inner output bump electrodes belonging to the second inner output bump electrode row are substantially the same and at the same time, constant.

17. The semiconductor integrated circuit device for driving a display device as described above in any one of items 14 to 16, wherein a center position, in a pitch direction, of each of the first inner output bump electrodes belonging to the first inner output bump electrode row and a center position, in a pitch direction, of each of the second inner output bump electrodes belonging to the second inner output bump electrode row are each substantially shifted from a center position, in a pitch direction, of an interconnect corresponding thereto on the side of the display device.

18. The semiconductor integrated circuit device for driving a display device as described above in any one of items 14 to 17, further comprising: (d) a bump electrode row for I/O or power supply terminals arranged along and in the vicinity of the second long side over the device surface of the rectangular semiconductor chip; wherein an area of each of bump electrodes for I/O or power supply terminals belonging to the bump electrode row for I/O or power supply terminals is greater than the area of each of the first inner output bump electrodes belonging to the first inner output bump electrode row and the area of each of the second inner output bump electrodes belonging to the second inner output bump electrode row.

19. The semiconductor integrated circuit device for driving a display device as described above in any one of items 14 to 18, wherein the display device is a liquid crystal display device.

20. A manufacturing method of a semiconductor integrated circuit device for driving a display device, comprising the following steps of: (x) forming, over the device surface of a wafer, a plurality of rectangular semiconductor chip regions having first and second short sides and first and second long sides at least 5 times longer than the short side; and (y) carrying out an electrical test of at least one of the rectangular semiconductor chip regions; wherein each of the rectangular semiconductor chip regions has the following: (a) an outer output bump electrode row for outputting a display device drive signal which electrode row is placed along and in the vicinity of the first long side; and (b) an inner output bump electrode row for outputting a display device drive signal which electrode row is placed along, more inward than, and in the vicinity of the outer output bump electrode row for outputting a display device drive signal; wherein (1) outer output bump electrodes belonging to the outer output bump electrode row and inner output bump electrodes belonging to the inner output bump electrode row each have a major portion containing a gold-based metal having gold as a main component; wherein (2) the width of each of the inner output bump electrodes along the first long side is made wider than the width of each of the outer output bump electrodes along the first long side; and wherein (3) the electrical test in the step (y) is performed by not bringing a probe needle into contact with each of the outer output bump electrodes but bringing the probe needle into contact with the other bump electrodes not belonging to the outer output bump electrode row.

21. The manufacturing method of a semiconductor integrated circuit device for driving a display device as described above in item 20, wherein each of the outer output bump electrodes belonging to the outer output bump electrode row has substantially the same area as each of the inner output bump electrodes belonging to the inner output bump electrode row.

22. The manufacturing method of a semiconductor integrated circuit device for driving a display device as described above in item 20 or 21, wherein each of the outer output bump electrodes belonging to the outer output bump electrode row and each of the inner output bump electrodes belonging to the inner output bump electrode row are formed over respectively corresponding aluminum-based metal bonding pads having aluminum as a main component; and wherein the area of the outer output bump electrodes and the area of the inner output bump electrodes are greater than the area of the respectively corresponding bonding pads.

23. The manufacturing method of a semiconductor integrated circuit device for driving a display device as described above in any one of items 20 to 22, wherein the pitch of the outer output bump electrodes belonging to the outer output bump electrode row and the pitch of the inner output bump electrodes belonging to the inner output bump electrode row are substantially the same and at the same time, constant.

24. The manufacturing method of a semiconductor integrated circuit device for driving a display device as described above in any one of items 20 to 23, wherein a center position, in a pitch direction, of each of the inner output bump electrodes belonging to the inner output bump electrode row is substantially shifted from a center position, in a pitch direction, of an interconnect corresponding thereto on the side of the display device.

25. The manufacturing method of a semiconductor integrated circuit device for driving a display device as described above in any one of items 20 to 24, further comprising: (c) a bump electrode row for I/O or power supply terminals arranged along and in the vicinity of the second long side; wherein an area of each of bump electrodes for I/O or power supply terminals belonging to the bump electrode row for I/O or power supply terminals is greater than the area of each of the inner output bump electrodes belonging to the inner output bump electrode row.

26. The manufacturing method of a semiconductor integrated circuit device for driving a display device as described above in any one of items 20 to 25, wherein the display device is a liquid crystal display device.

27. The manufacturing method of a semiconductor integrated circuit device for driving a display device as described above in any one of items 20 to 26, wherein the probe needle is a gold-based metal probe needle having gold as a main component thereof.

### [Explanation of Description Manner, Basic Terms, and Usage in the Present Application]

1. In the present application, a description in the embodiments will be made after divided in a plurality of sections if necessary for convenience's sake. These sections are not independent each other, but they may each be a part of a single example or one of them may be a partial detail of the other or a modification example of a part or whole of the other one unless otherwise specifically indicated. In principle, a description on a portion similar to that described before is not repeated. Moreover, when a reference is made to constituent elements of the embodiments, they are not essential unless otherwise specifically indicated, limited to the number theoretically, or principally apparent from the context that it is not.

2. With regard to any material, any composition or the like in the description of embodiments, the term “X made of A” or the like does not exclude X having, as a main constituent component thereof, an element other than A unless otherwise specifically indicated or principally apparent from the context that it is not. For example, the term “X made of A” means that “X containing, as a main component thereof, A”. It is needless to say that, for example, the term “silicon member” is not limited to a member made of pure silicon but also a member containing a SiGe alloy, another multi-element alloy having silicon as a main component, an additive, or the like.

Similarly, the term “aluminum interconnect”, “aluminum pad”, “gold bump” or the like means not only a pure one but that having aluminum or gold as a main component. The expression means that the major portion of the interconnect, pad or the like is made of such a material. It is needless to say that the expression does not always mean that the entirety of the interconnect, pad, or the like is made of such a material.

3. Preferred examples of the shape, position, attribute and the like will be shown, however, it is needless to say that they are not strictly limited to the preferred examples unless otherwise specifically indicated or apparent from the context that it is not.

4. When a reference is made to a specific number or amount, the number or amount may be greater than or less than the specific number or amount unless otherwise specifically indicated, limited to the specific number or amount theoretically, or apparent from the context that it is not.

5. The term “wafer” usually means a single crystal silicon wafer over which a semiconductor integrated circuit device (which may be a semiconductor device or an electronic device) is to be formed. It is however needless to say that it embraces a composite wafer of a semiconductor layer with an insulating substrate such as epitaxial wafer, SOI substrate and LCD glass substrate.

6. The term “bonding pad” as used herein means an aluminum-based pad or the like over which a bump structure is to be formed. The bonding pad is not limited to an aluminum-based one but it may be a copper-based one.

### Embodiments

The embodiments of the invention will hereinafter be described specifically. In all the drawings, the same or like members will be identified by the same or like symbols or reference numerals and overlapping descriptions will be omitted in principle.

Sections 1 to 3 are mainly related to the first layout of drive output bump electrodes (in which the bump electrodes have the following relationship in width: outer drive output bump electrodes<first inner drive output bump electrodes<second inner drive output bump electrodes). Section 4 is mainly related to the second layout of drive output bump electrodes (in which the bump electrodes have the following relationship in width: outer drive output bump electrodes<first inner drive output bump electrodes=second inner drive output bump electrodes). Descriptions on the whole layout in Sections 1 and 2 and a description on Section 3 except for a specific bump electrode layout are common to the layout example of Section 4. The descriptions on Sections 1 to 3 can be applied to Section 4 if the bump electrode layout of the former sections is replaced with the specific bump electrode layout of Section 4. With regard to common portions, the description on the preceding sections is therefore not repeated in principle.

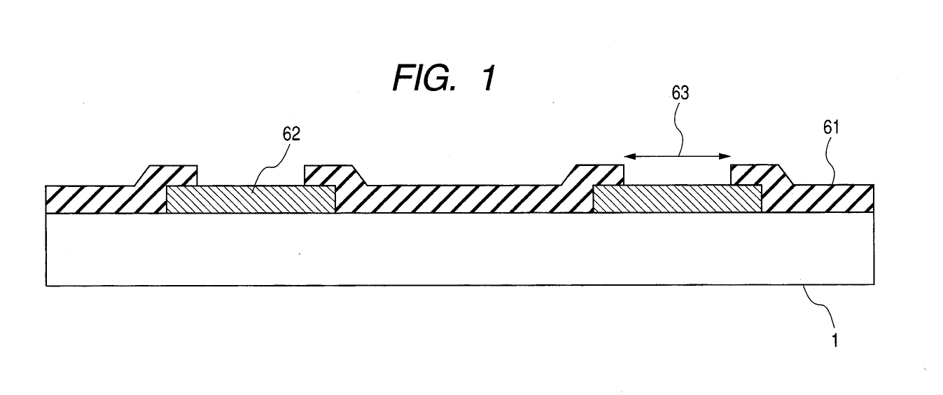

### 1. Description (Based on Mainly FIGS. 1 to 7) of a Wafer Process and the Like in the Manufacturing Method of the Semiconductor Integrated Circuit Device According to One Embodiment of the Present Application (First Layout of Drive Output Bump Electrodes)

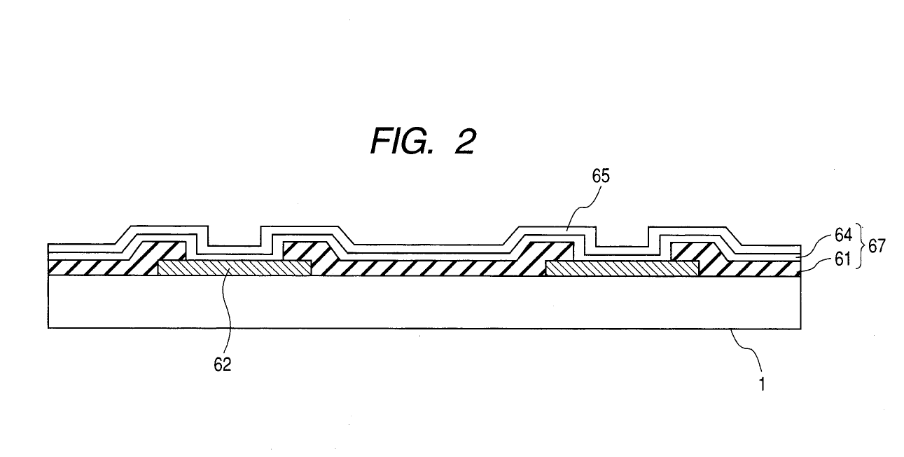

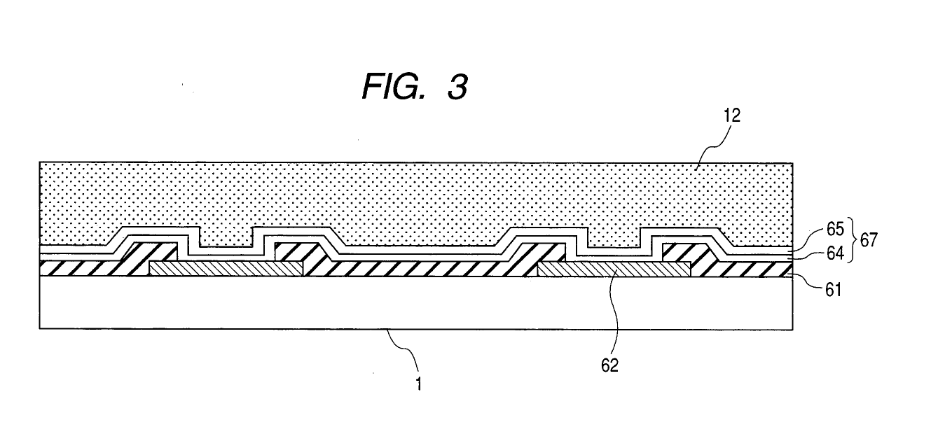

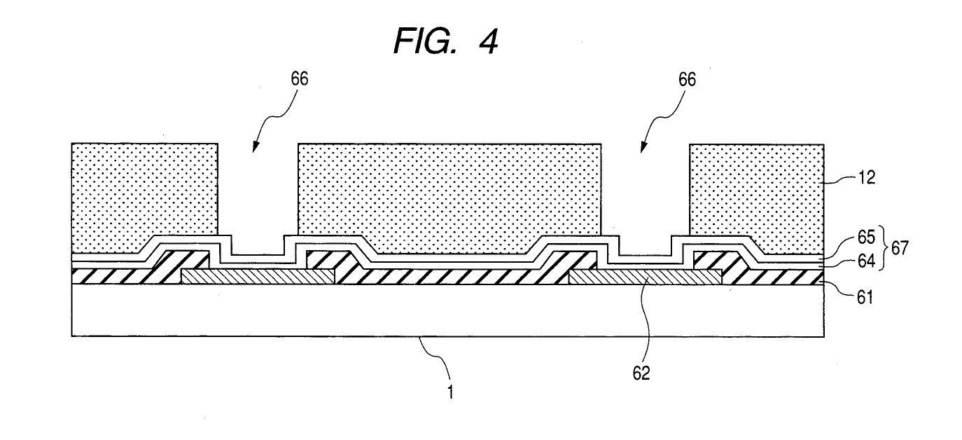

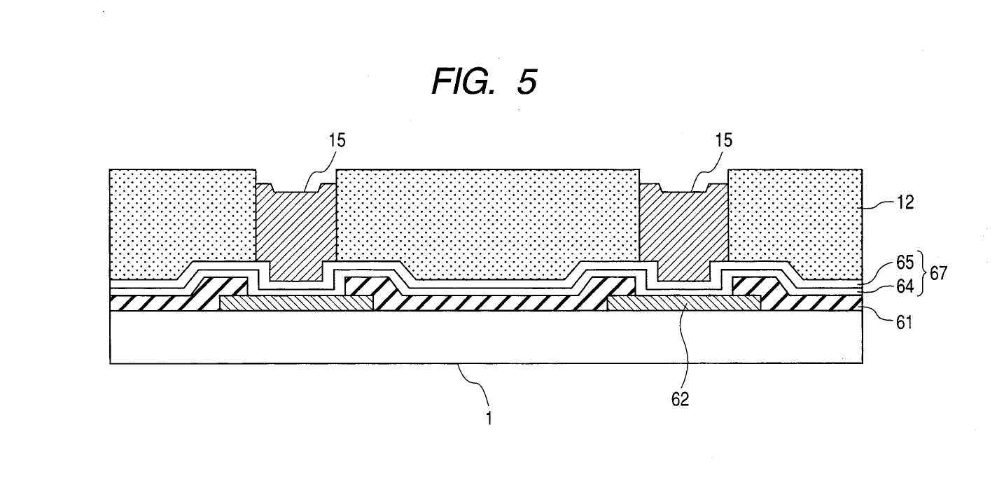

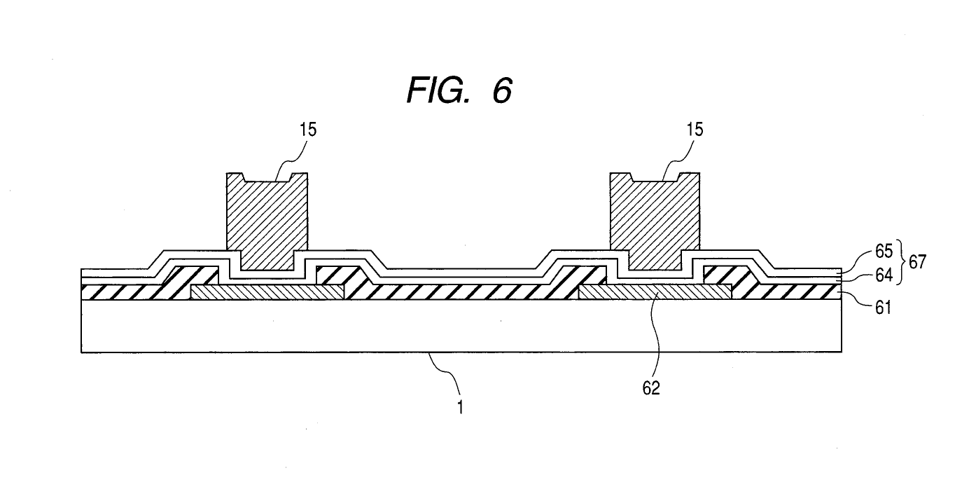

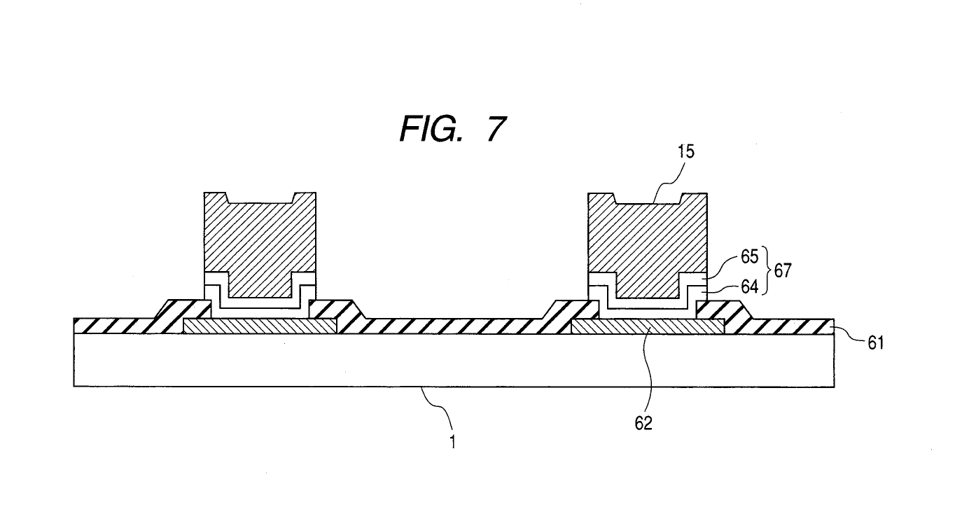

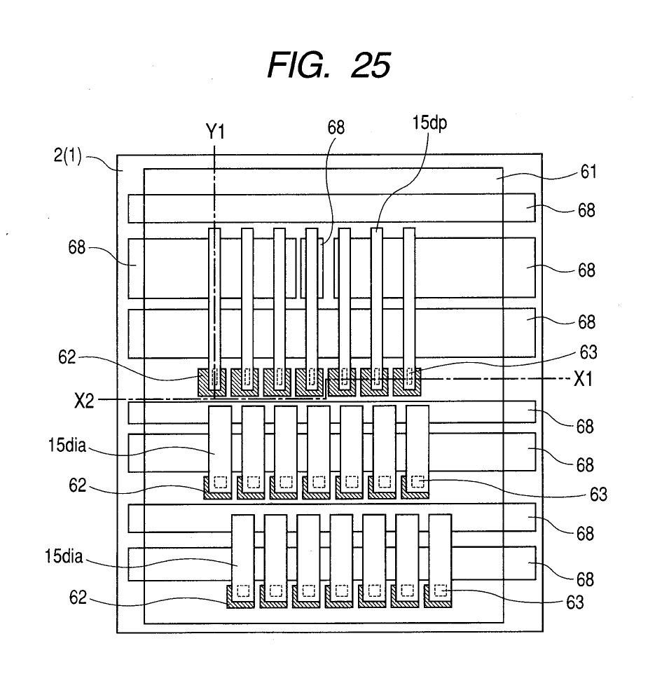

Next, a bump formation process in the manufacturing method of the semiconductor integrated circuit device according to the embodiment of the invention will be described based on FIGS. 1 to 7. The cross-section shown therein (the repetition number of bumps is two in these cross-sections) basically corresponds to the X2-X1 cross-section of FIG. 25. As illustrated in FIG. 1, over the main surface of a wafer 1 having thereover many devices and interconnects (made of a silicon oxide film or various metal layers), a final passivation film 61 such as silicon nitride (not only an inorganic film but also an organic film may be used) is formed. In a portion of the final passivation film corresponding to an aluminum pad 62, a pad opening 63 is placed. Then, as illustrated in FIG. 2, a titanium film 64 (lower layer) having, for example, a thickness of about 175 μm and a palladium film 65 (upper layer) having, for example, a thickness of about 175 μm are formed successively as a UBM (Under Bump Metal) film 67 by sputtering (these UBM materials are shown exemplary only and use of another similar material is not excluded. For example, the palladium film may be replaced with a gold film, but use of the palladium film leads to improvement in reliability. In addition, palladium is advantageous over gold in a material cost). As illustrated in FIG. 3, a positive resist film 12 having a thickness of, for example, from about 19 to 25 μm (for example, 20 μm) is formed over the under bump metal film by using an application system. The resist solution to be used here is, for example, “PMER P-LA900PM”, trade name; of a diazo/naphthoquinone/novolac positive resist for thick film, product of Tokyo Ohka Kogyo Co., LTD. The application type resist may be replaced with a film resist. As illustrated in FIG. 4, the resist film is exposed and developed to form an opening 66. As illustrated in FIG. 5, the opening 66 is then filled with a gold layer which has a thickness of, for example, about 15 μm and will be a bump electrode 15 by electroplating. As illustrated in FIG. 6, the resist film 12 is then removed. Finally, as illustrated in FIG. 7, an unnecessary portion of the UBM film is removed selectively by wet etching with the gold bump 15 as a mask. As a result, a bump electrode is almost completed. The gold bump 15 is usually made of a relatively pure gold material (having usually a Vicars hardness of from about 30 to 110). It can however be made of a gold-based alloy having gold as a main component thereof.

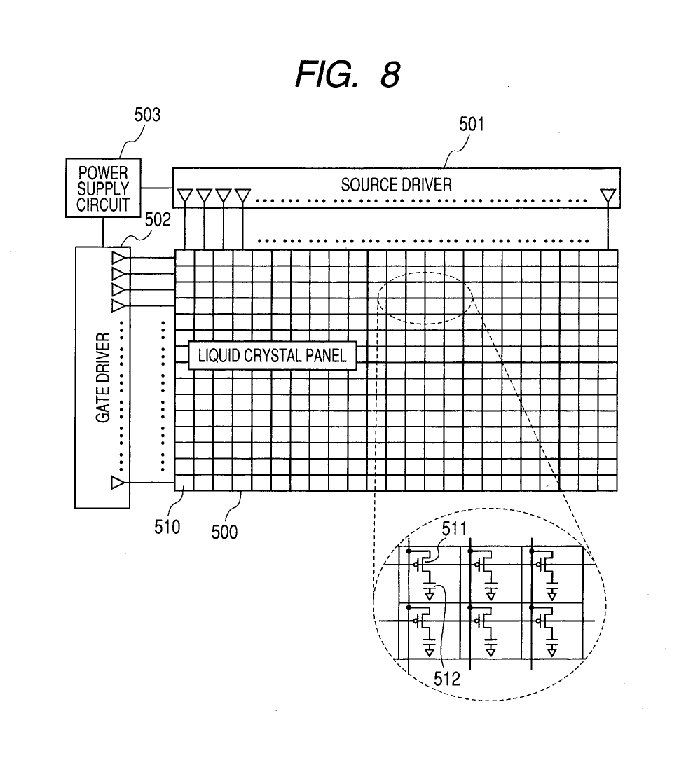

### 2. Description on the Device, Circuit Configuration, and the Like of the Semiconductor Integrated Circuit Device According to the Embodiment of the Invention (Based on Mainly FIGS. 8 to 11, and FIG. 20)

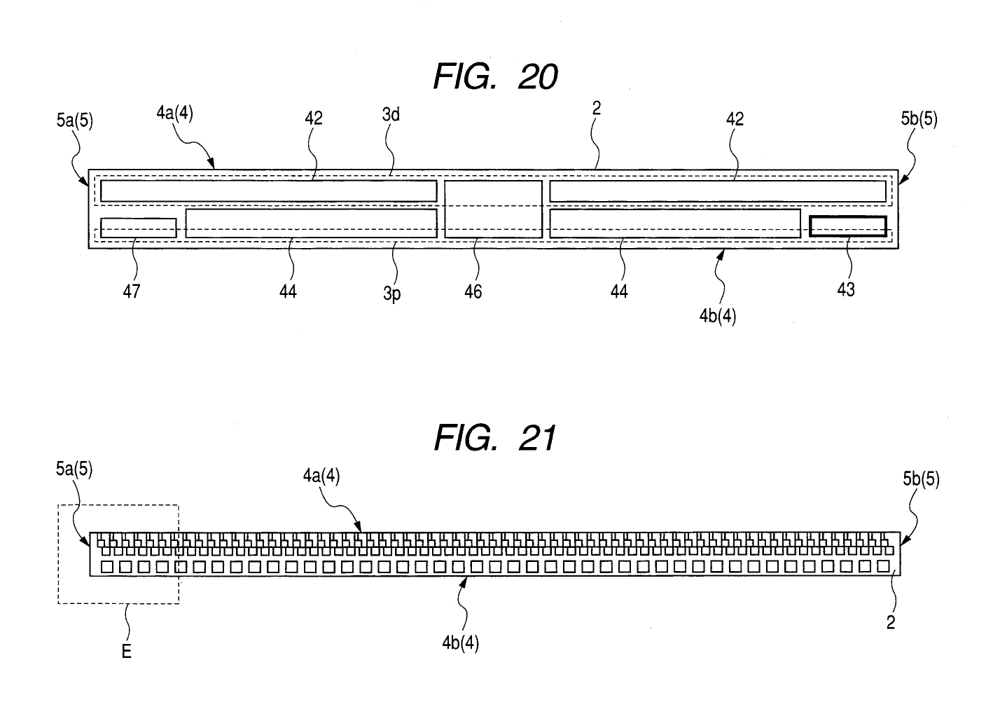

FIG. 20 is an overall layout diagram illustrating the upper surface of a semiconductor chip of the semiconductor integrated circuit device according to the embodiment of the invention. Based on this diagram, the device, circuit configuration, and the like of the semiconductor integrated circuit device according to each embodiment of the invention will be described. In the present embodiment, a semiconductor integrated circuit device for driving a liquid crystal display device (LCD driver) is exemplified as IC for LCD.

FIG. 20 is a typical circuit diagram over a chip 2 of IC for LCD. In this example, the IC for LCD is comprised of circuit blocks such as an in-chip power supply circuit portion 43, a controller portion 46, a nonvolatile redundant fuse circuit portion 47, a pair of memory circuit portions 44, and driver circuit portions 42 such as source/driver circuit portion and gate driver circuit portion. Of these, the gate driver circuit portion 42 and the in-chip power supply circuit portion 43 and the like are required to have a particularly high withstand voltage. The chip 2 of the IC for LCD is typically an elongate rectangular shape and has long sides 4 (first long side 4a, second long side 4b) at least five times longer than short sides 5 (first short side 5a, second short side 4b). In this example, the short side is 0.7 mm and the long side is 11 mm. The long side 4 is at least 15 times longer than the short side 5 (this size is almost similar in the example of FIG. 21). The long side is usually from about 8 times to 20 times greater than the short side.

Based on FIG. 8, a circuit diagram showing the coupling relationship between the semiconductor integrated circuit device (liquid crystal driver) according to the embodiment of the invention and a liquid crystal panel (liquid crystal display device) will next be described. As illustrated in FIG. 8, a liquid crystal panel 500 is coupled to an LCD driver necessary for driving this liquid crystal panel. In each pixel 510 of the liquid crystal panel 500, a transistor 511 and a capacitor 512 are arranged as illustrated in the diagram. Transistors arranged in the perpendicular direction in this diagram have a source terminal in common and transistors arranged in a horizontal direction of the diagram also have a gate terminal in common.

In order to drive the liquid crystal panel 500, a source driver 501 to be coupled with a source common terminal and having a function of applying a gradation voltage which will be a color display data, a gate driver 502 to be coupled with a gate common terminal and having a function of conducting display control of pixels in a horizontal direction in this diagram, and a power supply circuit 503 having a function of generating a voltage necessary for operating them are usually required. They are usually called “LCD drivers”. The source driver 501, the gate driver 502, and the power supply circuit 503 are integrated on a single chip 2 (FIG. 20) individually or integrated thereon after some functions are combined.

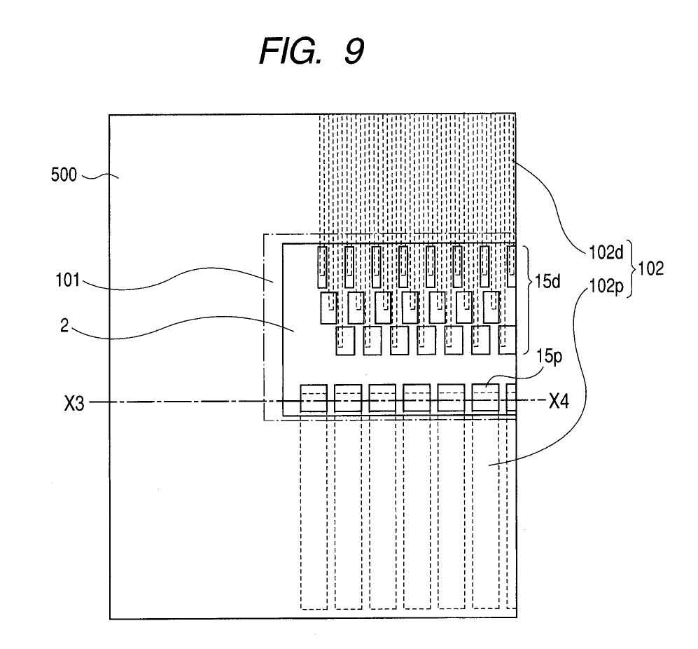

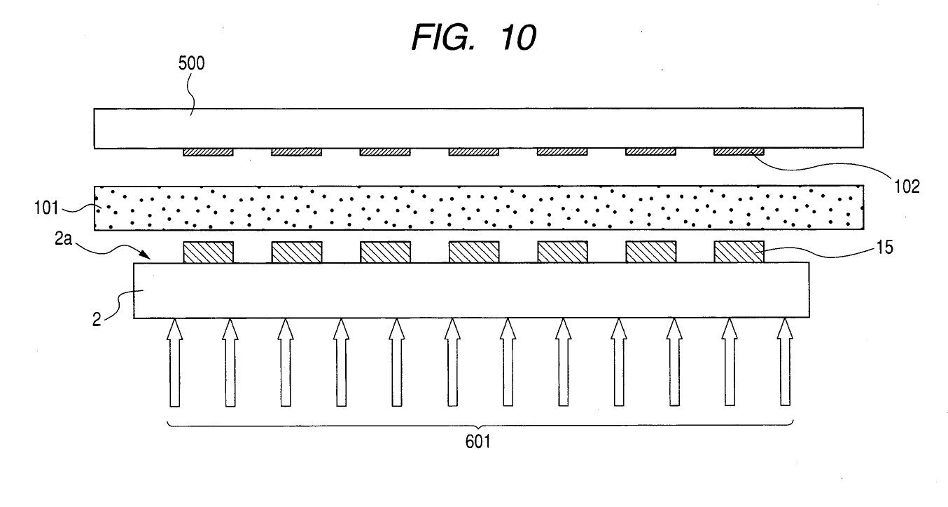

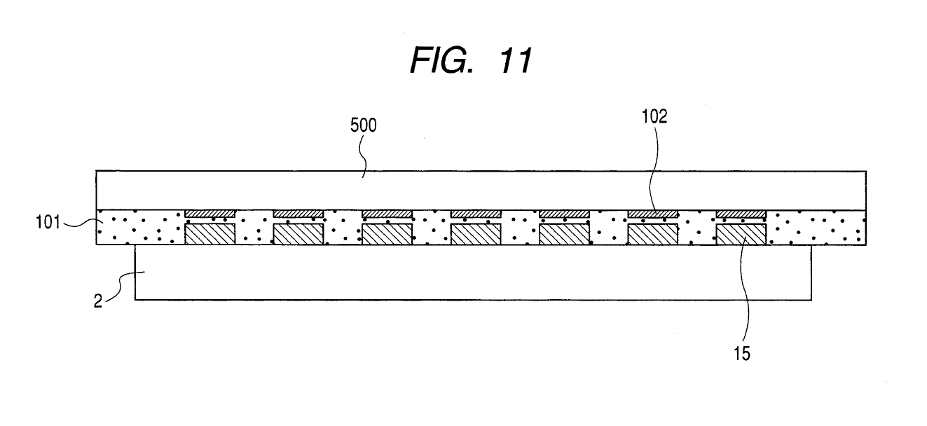

A specific layout of a coupled portion of the liquid crystal panel 500 and the semiconductor chip 2 for liquid crystal driver will next be described based on FIG. 9. As illustrated in FIG. 9, FIG. 10 (the X3-X4 cross-section of FIG. 9 before contact bonding), and FIG. 11 (the X3-X4 cross-section of FIG. 9 after contact bonding), ITO leads 102 such as a drive output ITO lead 102d and a non-drive output ITO lead 102p are formed over a glass substrate of the liquid crystal panel 500 and while facing them to bump electrodes 15 such as drive output bump electrodes 15d and non-drive output bump electrodes (I/O and power supply bump electrodes) 15p over the device surface 2a of the semiconductor chip 2 for liquid crystal driver, the resulting glass substrate and the bump electrodes are contact bonded via ACF, that is, an anisotropic conductive film 101. The width (for example, about 50 μm) of the non-drive output bump electrode 15p (I/O and power supply bump electrode) is typically much greater than the width (for example, from about 10 to 25 μm) of the drive output bump electrode 15d.

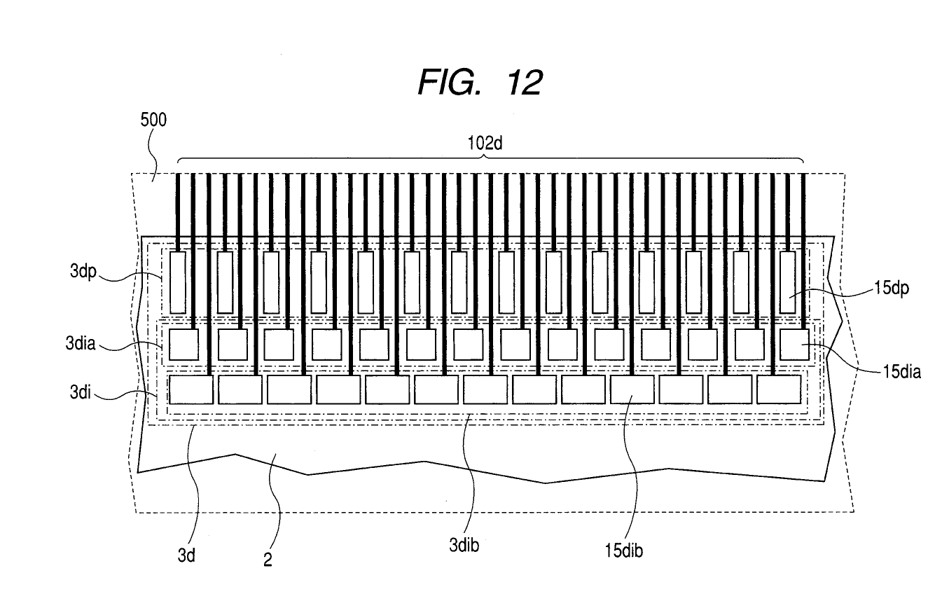

3. Description on a Wafer Probe Testing Step and the Like in the Manufacturing Method of the Semiconductor Integrated Circuit Device (Liquid Crystal Driver) According to the Embodiment of the Invention (Mainly from FIGS. 12 to 19)

Based on the above descriptions, the wafer probe testing step in the manufacturing method of the semiconductor integrated circuit device (liquid crystal driver) according to the embodiment of the invention will next be described.

First, referring to FIG. 12, a drive output bump electrode row 3d over the semiconductor chip 2, layout of the drive output bump electrodes 15d configuring it, and the relationship between them and drive output ITO leads 102d over the glass substrate of the liquid crystal panel 500 will hereinafter be described. In this example, as illustrated in FIG. 12, outer drive output bump electrodes 15dp belonging to an outer output bump electrode row 3dp each have an elongate and rectangular shape similar to typical gold bump electrodes (the outer output bump electrode row 3dp has a narrow width in an extending direction thereof). Inner drive output bump electrodes 15di belonging to an inner output bump electrode row 3di each have a rectangular shape with a greater width than that of the outer drive output bump electrodes 15dp (the inner output bump electrode row 3di has a narrow width in an extending direction thereof). The inner output bump electrode row 3di may be a single row but in this example, it is a double row comprised of a first inner output bump electrode row 3dia and a second inner output bump electrode row 3dib in order to increase the number of output terminals (it may usually be comprised of a plurality of rows such as two or three rows). When the width of first inner drive output bump electrodes 15dia belonging to the first inner output bump electrode row 3dia is compared with that of second inner drive output bump electrodes 15dib belonging to the second inner drive output bump electrode row dib, the width of the second inner drive output bump electrodes 15dib is wider. It is however to be noted that the drive output bump electrodes 15d belonging to the drive output bump electrode row 3d have almost the same area as each other (although they may have a different area, it is usually standardized to have almost the same area).

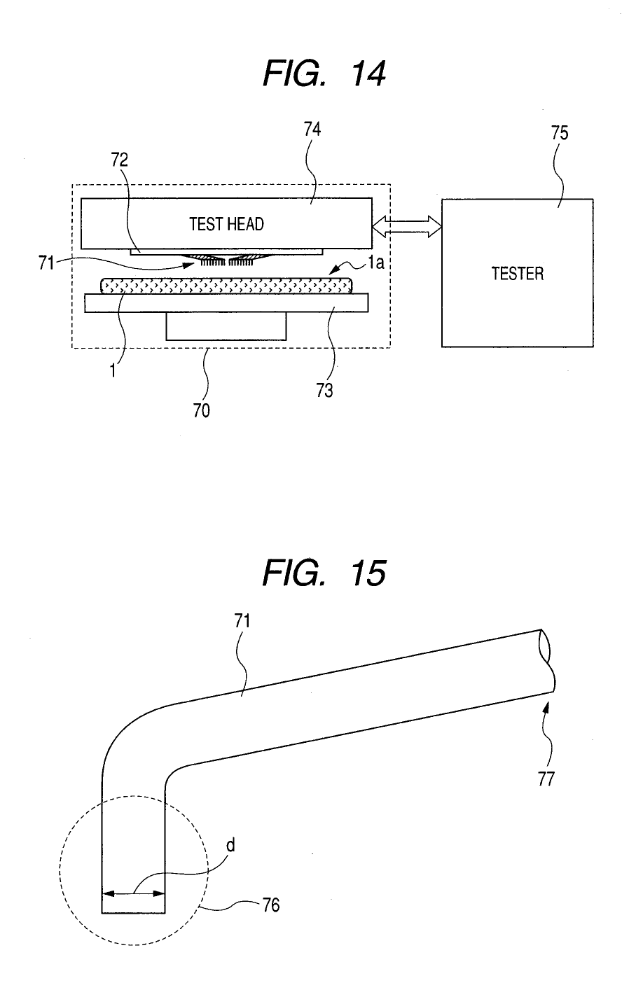

Next, wafer probe testing of the chip region 2a (wafer 1) in which these drive output bump electrodes 15d are laid out will be described. FIG. 14 is a schematic cross-sectional view of a wafer prober 70 upon wafer probe testing. As illustrated in FIG. 14, the wafer 1 is placed on a wafer stage 73 with a device surface 1a up. Over the wafer 1, there is a test head 74 for sending/receiving test signals and the like between the test head and a tester 75. Under the test head 74 a probe card 72 (for example, a cantilever type probe card) is set. A number of probe needles 71 protrude from the probe card 72 to the device surface 1a of the wafer 1.

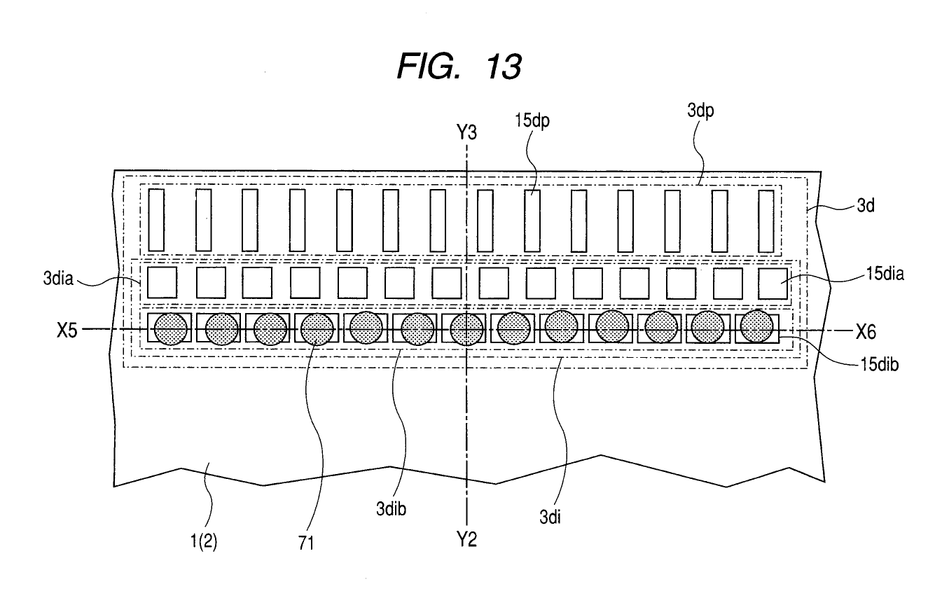

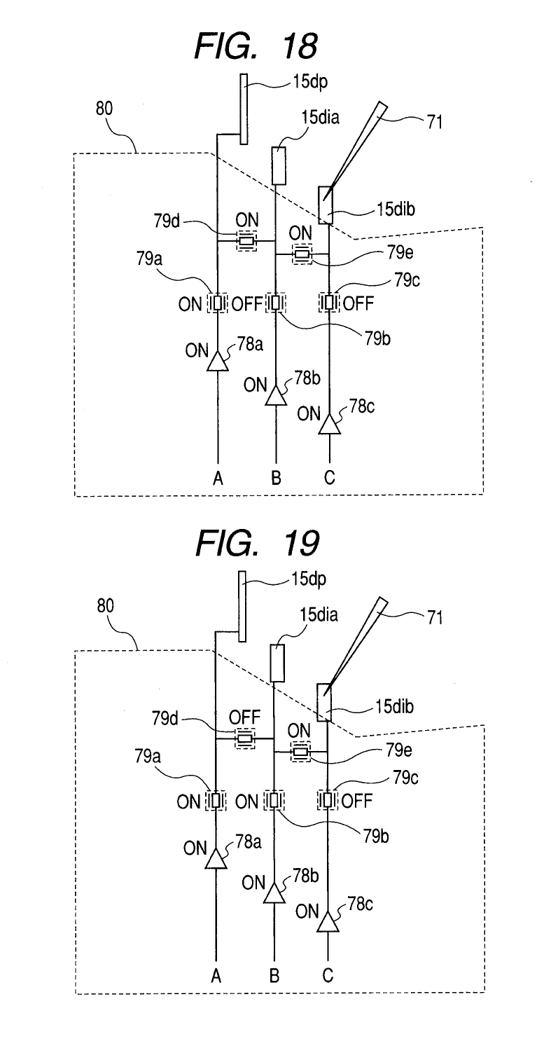

A contact position of the probe needle 71 upon wafer probe testing will hereinafter be described. As illustrated in FIG. 13, the wafer probe testing is performed, for example, while the probe needle 71 is in contact only with each of the second inner drive output bump electrodes 15dib. As illustrated in FIGS. 17 to 19, only contact of the probe needle 71 with one of wide and innermost drive output bump electrodes 15dia by temporal switching through a test circuit 80 comprised of buffers 78a, 78b, and 78c, transfer gate MISFET switches 79a, 79b, 79c, 79d, and 79e, and the like makes it possible to test output signals A, B, and C including signals from the other electrodes, that is, the drive output bump electrodes 15dia of a middle row and the drive output bump electrodes 15dp on the outer side. Described specifically, FIG. 17 illustrates measurement of the output signal C to be essentially output to the drive output bump electrode 15dib. FIG. 18 illustrates measurement of the output single A to be essentially output to the drive output bump electrode 15dia. FIG. 19 illustrates the measurement of the output signal B to be essentially output to the drive output bump electrode 15dp.

The structure in the vicinity of the tip of the probe needle 71 will hereinafter be described referring to FIG. 15 (the Y2-Y3 cross-section of FIG. 13). As illustrated in FIG. 15, the probe needle root portion 77 is a little wider, but the diameter d of the probe needle tip portion 76 (almost perpendicular to the needle) is about 15 μm. The material of the probe needle is, for example, an alloy having gold as a main component. The alloy is made of, for example, 70 wt. % of gold and 30 wt. % in total of copper and silver. The needle made of such a material has a Vicars hardness of about 360. The needle pressure upon contact is usually from about 0.1 to 0.2 g upon contact.

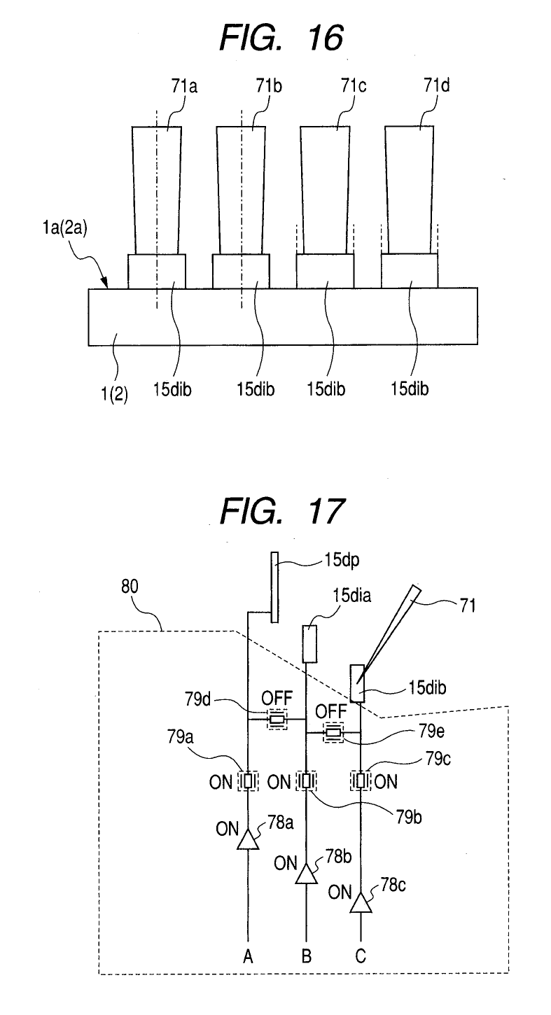

Moreover, as illustrated in FIG. 16 (part of the X5-X6 cross-section of FIG. 13), the diameter (for example, from about 20 to 25 μm) of the second inner drive output bump electrodes 15dib over the device surface 1a (2a) of the wafer 1 (chip region 2) is greater than the diameter of the tip portion of the probe needle 71 so that the tip portion of the probe needle 71 does not get out of the bump electrode not only when probe needles are, like probe needles 71a and 71b, aligned precisely but also when probe needles are, like probe needles 71c and 71d, are slightly off the center of the bump electrode.

The repetition of a contacting step of the probe needle 71 with a narrow bump electrode such as the outer drive output bump electrodes 15dp as illustrated in FIG. 13, on the other hand, leads to wear of only the tip portion 76 of the probe needle that is brought into contact with the bump electrode. As a result, the portion of the probe needle getting out of the bump electrode protrudes and the probe needle having such a protrusion cannot have stable contact characteristics.

4. Concrete Descriptions on in-Chip Bump Electrode Layout and the Like of the Semiconductor Integrated Circuit Device (Liquid Crystal Driver) According to Another Embodiment (Layout of Second Drive Output Bump Electrodes) of the Invention (FIG. 20 and FIGS. 21 to 27)

A liquid crystal driver chip 2 having a similar circuit layout to that described in Section 2 based on FIG. 20 but slightly different in the layout of drive output bump electrodes will next be described.

FIG. 21 illustrates the overall layout of bump electrodes in a chip. It is difficult to describe the layout of bump electrodes by using such an overall chip view so that details will be described referring to an enlarged portion E of the end portion of the chip.

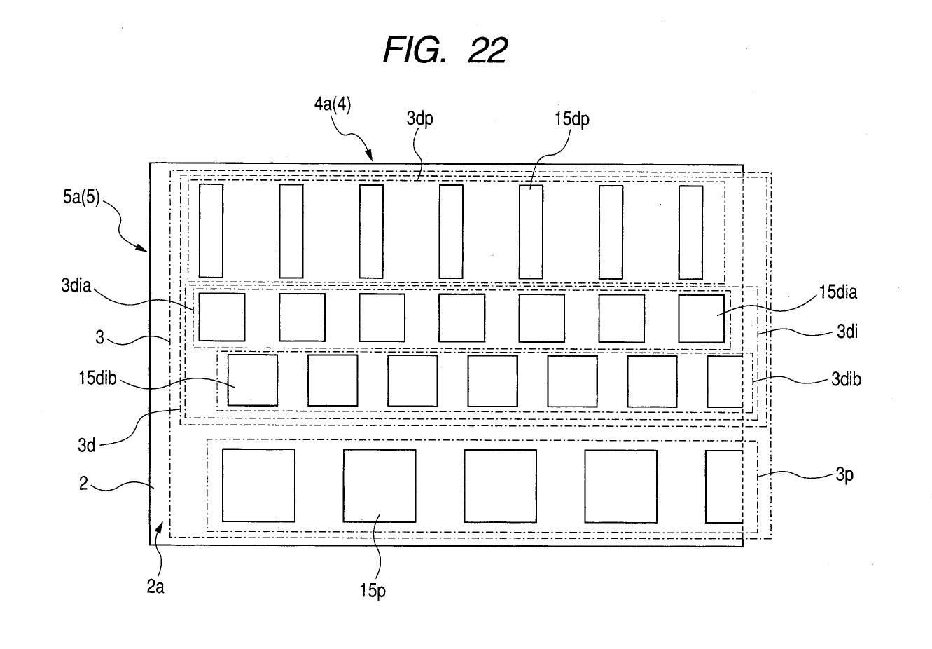

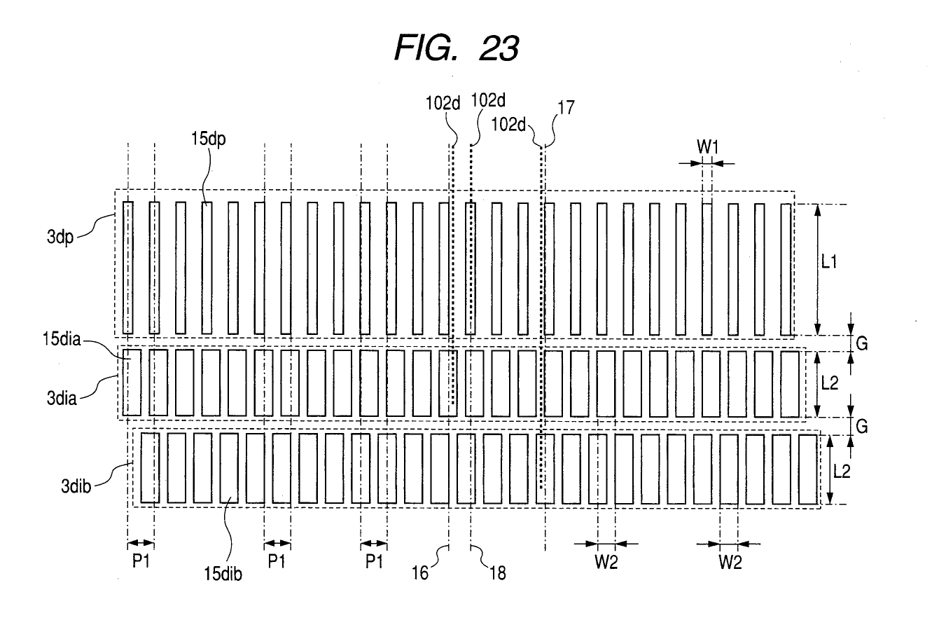

FIG. 22 (in which the space between the drive output bump electrode row 3d and a non-drive output bump electrode row 3p is narrow for convenience of drawing, but their space is actually about 300 μm) is an enlarged plan view of the layout of the bump electrodes in the enlarged chip-end-portion E of FIG. 21. As illustrated in FIG. 22, the inner output bump electrode row 3di is, similar to the above-described example, a double row (it may be a single row when the number of output signals is small) (it may be comprised of many rows similar to the above-described example). A difference resides in that the first inner drive output bump electrodes 15dia belonging to the first inner output bump electrode row 3dia and the second inner drive output bump electrodes 15dib belonging to the second inner output bump electrode row 3dib have substantially the same width as each other. It is however to be noted that the non-drive output bump electrodes 15p (I/O and power supply bump electrodes) belonging to the non-drive output bump electrode row 3p has, similar to the above-described example, the greatest width among all the bump electrodes 15 (for example, FIG. 7, 10, or 11) belonging to the bump electrode row 3. In addition, similar to the above-described example, the width of the outer drive output bump electrodes 15dp belonging to the outer output bump electrode row 3dp are narrower than that of the inner output bump electrode row 3di and the non-drive output bump electrodes 15p. Various drive output bump electrodes 15d have substantially the same area as each other.

FIG. 23 is a plan layout diagram illustrating the layout of the drive output bump electrodes 15d of FIG. 22 in a more realistic form. As illustrated in FIG. 23, the outer drive output bump electrodes 15dp each have a width W1 of, for example, about 10 μm and a length L1 of, for example, about 150 μm, and they are arranged at a pitch P1 of, for example, about 30 μm. Similarly, the first inner drive output bump electrodes 15dia and the second inner drive output bump electrodes 15dib each have a width W2 of, for example, about 20 μm and a length L2 of, for example, about 75 μam and they are arranged at a pitch P1 of, for example, about 30 μm (equal to the pitch of the outer drive output bump electrodes 15dp). A gap G between various drive output bump electrode rows 3d is about 20 μm. The mutual positions of the various drive output bump electrode rows 3d in a pitch direction are determined by the positional relationship relative to the drive output ITO leads 102d. This means that the outer drive output bump electrodes 15dp are arranged so that the center line 18 thereof substantially coincides with the drive output ITO leads 102d to be coupled therewith. The first inner drive output bump electrodes 15dia are arranged so that the center line 16 thereof is substantially shifted from the drive output ITO leads 102d to be coupled therewith. The second inner drive output bump electrodes 15dib are arranged so that the center line 17 thereof is substantially shifted, in a direction contrary to the shifted direction in the case of the first inner drive output bump electrodes 15dia, from the drive output ITO leads 102d to be coupled with the second inner drive output bump electrodes.

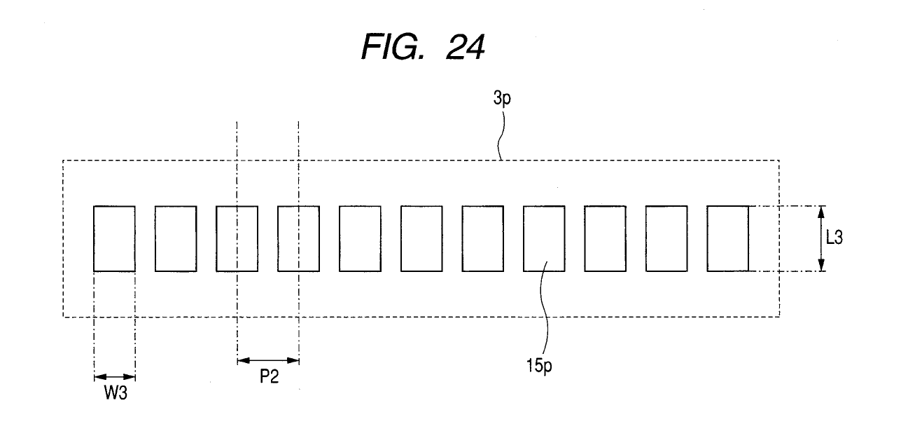

FIG. 24 is a plan layout diagram illustrating the layout of the non-drive output bump electrodes 15p belonging to the non-drive output bump electrode row 3p of FIG. 22 in a more realistic form. As illustrated in FIG. 24, the non-drive output bump electrodes 15p each have a width W3 of, for example, about 50 μm and a length L3 of, for example, about 80 μm and they are arranged with a pitch P2 of, for example, about 70 μm.

FIG. 25 illustrates the relationship among the drive output bump electrodes 15d, underlying aluminum-based upper-level interconnects 68 (aluminum-based bonding pads 62 of the same layer), aluminum-based bonding pad openings 63, and the like illustrated in FIG. 23 after stepwise peeling of a final passivation film 61 and aluminum-based upper-layer interconnects 68 to facilitate understanding. The aluminum-based upper-level interconnects 68 below the finial passivation film 61 are actual interconnects or dummy interconnects. Existence of such interconnects contributes to planarization of the drive output bump electrodes 15d such as outer drive output bump electrodes 15dp, first inner drive output bump electrodes 15dia, and second inner drive output bump electrodes 15dib.

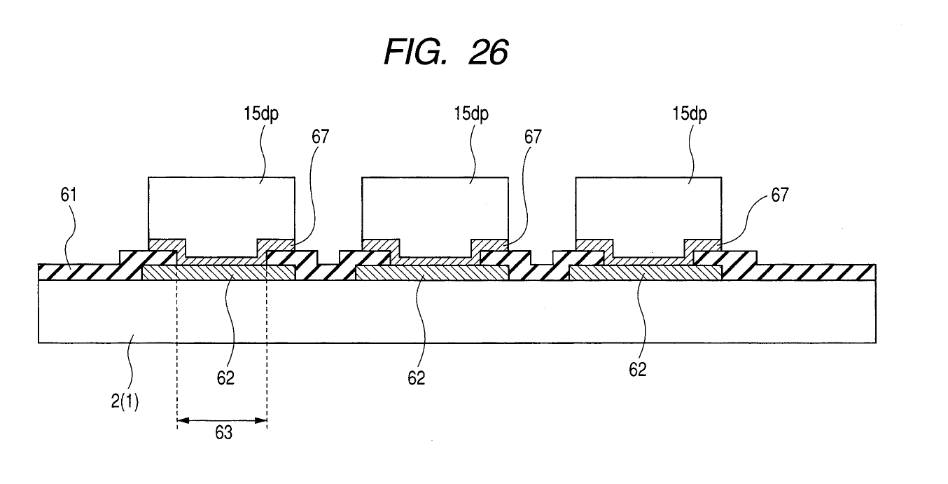

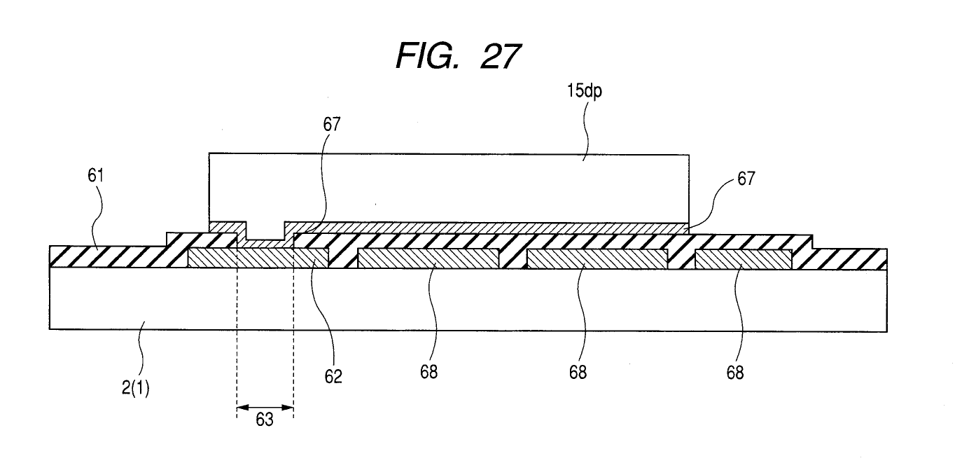

The X2-Y1 cross-section of FIG. 25 is shown in FIG. 27 and the X2-X1 cross-section is shown in FIG. 26. To avoid showing a similar diagram repeatedly, a description will be made with the outer drive output bump electrodes 15dp as an example. The other drive output bump electrodes 15d have almost a similar outline structure, though the number of the underlying aluminum-based interconnects 68 is different.

As illustrated in FIG. 26 (substantially corresponding to FIGS. 1 to 7) and FIG. 27, uppermost-level aluminum-based interconnects 68 are formed over a semiconductor chip (chip region; including some interconnect layers) 2 or a wafer (a semiconductor substrate including some interconnect layers) 1. Bonding pads 62 are formed in the same layer as the uppermost-level aluminum-based interconnects 68. A final passivation film 61 is formed over them and bonding pad openings 63 are formed therein. An under bump metal film 67 is patterned over the bonding pads 62 and also over the final passivation film 61. Gold bump electrodes 15 (outer drive output bump electrodes 15d) obtained by electroplating or the like are formed over the under bump metal film.

### 5. Description on the Relationship Among the First Layout of the Drive Output Bump Electrodes, the Second Layout of the Drive Output Bump Electrodes, and Wafer Probe Testing or Another Wafer Process (Mainly, FIGS. 12, 13, 21, 22, 25, and 27)

As illustrated in FIG. 20, it is difficult to extend the region occupied by the drive output bump electrode row 3d to the whole remaining region of the wafer because of limitation in layout or aluminum etching process. Described specifically, as illustrated in FIGS. 25 and 27, many aluminum-based interconnects 68 should be placed from the standpoint of planarization of the drive output bump electrodes 15d, but the terminal point of etching cannot be found easily when the area of the aluminum-based interconnects 68 exceeds a certain level. There is not a high degree of freedom in the layout of the drive output bump electrode row 3d and it is substantially limited to the example (first layout of the drive output bump electrodes) of FIG. 12 or 13, the example (second layout of the drive output bump electrodes) of FIG. 22, and modification examples thereof.

Examples of the modification examples include those similar to the above-described examples except for the omission of the second inner output bump electrode row 3dib. This layout is effective when the number of the drive output bump electrodes 15d is relatively small. In this case, wafer probe testing is performed by bringing the probe needle 71 into contact with the first inner drive output bump electrodes 15dia.

Since the width of the second inner drive output bump electrode 15dib can be made relatively wide, the example of FIG. 12 or 13 (first layout of the drive output bump electrodes) is advantageous when wafer probe testing is performed by bringing the probe needle 71 into contact with only the second inner drive output bump electrodes 15dib, among the drive output bump electrodes 15d. Due to lack of translational symmetry, the above example has difficulty in layout and requires complex arrangement of probe needles. In addition, the pitch tends to be a little wider. When they are laid out with translational symmetry, remarkable widening of the pitch may be inevitable. It is therefore necessary to determine the width of each of the first inner drive output bump electrodes 15dia and the second inner drive output bump electrodes 15dib to fall within a range permitting maintenance of translational symmetry.

Translational symmetry of a set of the outer drive output bump electrode 15dp, the first inner drive output bump electrode 15dia, and the second inner drive output bump electrode 15dib is established in the example (second drive output bump electrode layout) of FIG. 22, which facilitates layout of them and minimizes the pitch. Since the first inner drive output bump electrode 15dia and the second inner drive output bump electrode 15dib have the same shape and arranged at the same pitch, wafer probe testing can be carried out by bringing the probe needles into contact with both of them if necessary.

### 6. Summary

The inventions made by the present inventors were described specifically based on some embodiments. It is needless to say that the invention is not limited to them but can be changed without departing from the scope of the invention.

In the above embodiments, examples of wafer probe testing using a probe card having a cantilever type probe needle were described. It is needless to say that the invention is not limited to them but can also be applied to wafer probe testing using a probe card having an advanced probe needle making use of lithography or MEMS technology.

In the above embodiments, a gold-based probe needle was mainly described, but it is needless to say that probe needles made of tungsten or another material is also usable.

What is claimed is:

1. A semiconductor device, comprising:
a semiconductor substrate of a rectangular shape, the semiconductor substrate having a first long side and a second long side;
a plurality of first pads and a plurality of second pads formed over the semiconductor substrate;
a first insulating film formed over the first pads and the second pads and having a plurality of first openings and a plurality of second openings such that the first openings are formed at upper sides of corresponding ones of the first pads and the second openings are formed at upper sides of corresponding ones of the second pads,
a plurality of first bump electrodes of a rectangular shape formed over the first insulating film and electrically connected to corresponding ones of the first pads via the first openings, respectively, and
a plurality of second bump electrodes of a rectangular shape formed over the first insulating film and electrically connected to corresponding ones of the second pads via the second openings, respectively,
wherein the first bump electrodes and the second bump electrodes are arranged linearly in a first direction which is along the first long side,
wherein the first bump electrodes and the second bump electrodes are disposed closer to the first long side than the second long side in plan view,
wherein the first bump electrodes are disposed between the first long side and the second bump electrodes in plan view,
wherein each of the first bump electrodes and each of the second bump electrodes are configured such that long sides thereof extend in a second direction which is along a first short side of the semiconductor substrate,
wherein a first width of each of the second bump electrodes along the first direction is made wider than a second width of each of the first bump electrodes along the first direction, and
wherein a first length of each of the first pads along the second direction is made wider than a second length of each of the second pads along the second direction.

2. The semiconductor device according to claim 1,
wherein a first area of each of the first bump electrodes and a second area of each of the second bump electrodes are greater than a third area of each of the first pads and a fourth area of each of the second pads in plan view.

3. The semiconductor device according to claim 1, wherein a first pitch of the first bump electrodes and a second pitch of the second bump electrodes are substantially the same and constant.

4. The semiconductor device according to claim 1, wherein a center position, in the first direction, of each of the second bump electrodes is shifted from a center position, in the first direction, of each of the first bump electrodes.

5. The semiconductor device according to claim 1, further comprising:
a plurality of third bump electrodes of a rectangular shape formed over the semiconductor substrate,
wherein the third bump electrodes are arranged linearly in the first direction,
wherein the third bump electrodes are disposed closer to the second long side than the first long side in plan view, and
wherein a fifth area of each of the third bump electrodes is greater than a first area of each of the first bump electrodes and a second area of each of the second bump electrodes in plan view.

6. The semiconductor device according to claim 1, wherein the semiconductor device is a liquid crystal display device.

7. A semiconductor device, comprising:
a semiconductor substrate of a rectangular shape, the semiconductor substrate having a first long side and a second long side;
a plurality of first pads and a plurality of second pads formed over the semiconductor substrate;
a first insulating film formed over the first pads and the second pads and having a plurality of first openings and a plurality of second opening such that the first openings are formed at upper sides of corresponding ones of the first pads and the second openings are formed at upper sides of corresponding ones of the second pads,
a plurality of first bump electrodes of a rectangular shape formed over the first insulating film and electrically connected to corresponding ones of the first pads via the first openings, respectively, and
a plurality of second bump electrodes of a rectangular shape formed over the first insulating film and electrically connected to corresponding ones of the second pads via the second openings, respectively,
wherein the first bump electrodes and the second bump electrodes are arranged linearly in a first direction which is along the first long side,
wherein the first bump electrodes and the second bump electrodes are disposed closer to the first long side than the second long side in plan view,
wherein the first bump electrodes are disposed between the first long side and the second bump electrodes in plan view,
wherein each of the first bump electrodes and each of the second bump electrodes are configured such that long sides thereof extend in a second direction which is along a first short side of the semiconductor substrate,
wherein a first width of each of the second bump electrodes along the first direction is made wider than a second width of each of the first bump electrodes along the first direction,
wherein a first length of each of the first bump electrodes along the second direction is made wider than a second length of each of the second bump electrodes along the second direction, and
wherein a third length of each of the first pads along the second direction is made wider than a fourth length of each of the second pads along the second direction.

8. The semiconductor device according to claim 7,
wherein a first area of each of the first bump electrodes and a second area of the second bump electrodes are greater than a third area of each of the first pads and a fourth area of each of the second pads in plan view.

9. The semiconductor device according to claim 7, wherein a first pitch of the first bump electrodes and a second pitch of the second bump electrodes are substantially the same and constant.

10. The semiconductor device according to claim 7, wherein a center position, in the first direction, of each of the second bump electrodes is shifted from a center position, in the first direction, of each of the first bump electrodes.

11. The semiconductor device according to claim 7, further comprising:
a plurality of third bump electrodes of a rectangular shape formed over the semiconductor substrate,
wherein the third bump electrodes are arranged linearly in the first direction,
wherein the third bump electrodes are disposed closer to the second long side than the first long side in plan view, and
wherein a fifth area of each of the third bump electrodes is greater than a first area of each of the first bump electrodes and a second area of each of the second bump electrodes in plan view.

12. The semiconductor device according to claim 7, wherein the semiconductor device is a liquid crystal display device.

13. The semiconductor device according to claim 1, wherein the first bump electrodes and the second bump electrodes are formed such that the first bump electrodes and the second bump electrodes are arranged in a zigzag pattern in plan view.

14. The semiconductor device according to claim 5, wherein a third width of each of the third bump electrodes along the first direction is made wider than the first width and the second width.

15. The semiconductor device according to claim 1,
wherein a fourth width of each of the second openings along the first direction is made wider than a fifth width of each of the first openings along the first direction, and
wherein a third width of each of the first openings along the second direction is made wider than a fourth width of each of the second openings along the second direction.

16. The semiconductor device according to claim 1, wherein the first bump electrodes and the second bump electrodes are for outputting signals.

17. The semiconductor device according to claim 5, wherein the third bump electrodes are for I/O or power supply terminals.

18. The semiconductor device according to claim 1,
wherein the third area is greater than the fourth area in plan view.

19. The semiconductor device according to claim 7, wherein the first bump electrodes and the second bump electrodes are formed such that the first bump electrodes and the second bump electrodes arranged in a zigzag pattern in plan view.

20. The semiconductor device according to claim 11, wherein a third width of each of the third bump electrodes along the first direction is made wider than the first width and the second width.

21. The semiconductor device according to claim 1,
wherein a fourth width of each of the second openings along the first direction is made wider than a fifth width of each of the first openings along the first direction, and
wherein a fifth width of each of the first openings along the second direction is made wider than a sixth width of each of the second openings along the second direction.

22. The semiconductor device according to claim 7, wherein the first bump electrodes and the second bump electrodes are for outputting signals.

23. The semiconductor device according to claim 17, wherein the third bump electrodes are for I/O or power supply terminals.

24. The semiconductor device according to claim 8, wherein the third area is greater than the fourth area in plan view.
